(19) United States
(12) Patent Application Publication
(10) Pub. No.: US 2016/0020386 A1
(43) Pub. Date: Jan. 21, 2016

(54) METHOD OF MANUFACTURING MAGNETIC DEVICE

(71) Applicant: SAMSUNG ELECTRONICS CO., LTD., Suwon-si (KR)

(72) Inventors: Ki-woong KIM, Yongin-si (KR); Joon-myoung LEE, Suwon-si (KR); Woo-chang LIM, Seongnam-si (KR); Sang-yong KIM, Suwon-si (KR)

(21) Appl. No.: 14/678,069

(22) Filed: Apr. 3, 2015

(30) Foreign Application Priority Data
Jul. 21, 2014 (KR) 10-2014-0092080

(51) Int. Cl. H01L 43/12; C23C 14/34; C23C 14/58; H01L 43/08

(52) U.S. Cl. CPC H01L 43/12; H01L 43/08; C23C 14/34; C23C 14/5806

(57) ABSTRACT

Provided is a method of manufacturing a magnetic device, the method including forming a magnetic layer; forming a lower insulating layer on the magnetic layer using a first gas, which is an inert gas having a greater atomic weight than argon (Ar); and forming an upper insulating layer on the lower insulating layer using Ar gas.

### CROSS-REFERENCE TO RELATED APPLICATION

Korean Patent Application No. 10-2014-0092080, filed on Jul. 21, 2014, in the Korean Intellectual Property Office, and entitled: “Method of Manufacturing Magnetic Device,” is incorporated by reference herein in its entirety.

### BACKGROUND

Provided is a method of manufacturing a magnetic device, for example, to a method of manufacturing a magnetic device having a perpendicular magnetic anisotropy (PMA).

### SUMMARY

Embodiments may be realized by providing a method of manufacturing a magnetic device, the method including forming a magnetic layer; forming a lower insulating layer on the magnetic layer using a first gas, which is an inert gas having a greater atomic weight than argon (Ar); and forming an upper insulating layer on the lower insulating layer using Ar gas.

The magnetic layer may be a pinned layer or a free layer.

Forming the lower insulating layer may be performed under a pressure ranging from about 0.001 to about 0.1 mTorr.

Forming the lower insulating layer may include a sputtering process in which a metal oxide is used as a target.

The first gas may be krypton (Kr) gas.

Embodiments may be realized by providing a method of manufacturing a magnetic device, the method including forming a first lower insulating layer on a first magnetic layer; forming a first upper insulating layer on the first lower insulating layer; forming a second magnetic layer on the first upper insulating layer; and forming a second insulating layer on the second magnetic layer, the first lower insulating layer being formed using a first gas, which is an inert gas having a greater atomic weight than argon (Ar), and the first upper insulating layer being formed using Ar gas.

Either the first magnetic layer or the second magnetic layer may be a pinned layer, and the other of the first magnetic layer and the second magnetic layer may be a free layer.

The first lower insulating layer may directly contact the first upper insulating layer.

Forming the second insulating layer may include a sputtering process in which the first gas is used as a sputtering gas.

The method may further include, after forming the first lower insulating layer, a first heat treatment process in which the first lower insulating layer is heat-treated and a damage layer formed on an interface between the first magnetic layer and the first lower insulating layer is removed.

The method may further include, after forming the first lower insulating layer, performing a second heat treatment process in which the first lower insulating layer is heat-treated at a temperature higher than a temperature of the first heat treatment process and the first lower insulating layer is crystallized.

The first and second heat processes may be performed in an in-situ manner after forming the first lower insulating layer.

The method may further include performing a third heat treatment process in which the second insulating layer is heat-treated after forming the second insulating layer.

One or more of the first lower insulating layer, the first upper insulating layer, or the second insulating layer may include a metal oxide.

The metal oxide may include one or more of aluminum (Al), magnesium (Mg), tantalum (Ta), hafnium (Hf), or zirconium (Zr).

Embodiments may be realized by providing a method of manufacturing a magnetic device, the method including forming a magnetic layer; forming a lower insulating layer on the magnetic layer, including a sputtering process using a sputtering gas, the sputtering gas including Ar gas and an inert gas having a greater atomic weight than Ar; and heat treating the lower insulating layer.

During formation of the lower insulating layer a flow of the inert gas having a greater atomic weight than Ar may be decreased, a flow of Ar gas may be increased, and at a point in time, the flow of the inert gas having a greater atomic weight than Ar may be equal to the flow of Ar gas.

An initial flow of the inert gas having a greater atomic weight than Ar may be less than or equal to a final flow of Ar gas.

Only the inert gas having a greater atomic weight than Ar may be used during an early stage of the sputtering process.

Only Ar gas may be used during a late stage of the sputtering process.

### BRIEF DESCRIPTION OF THE DRAWINGS

Features will become apparent to those of skill in the art by describing in detail exemplary embodiments with reference to the attached drawings in which:

FIGS. 1A and 1B illustrate a magnetic device according to an embodiment;

FIGS. 2A and 2B illustrate conceptual views for explaining a principle which improves an operational property of a magnetic device, according to embodiments;

FIGS. 3A through 3K illustrate sequentially arranged cross-sectional views of a method of manufacturing a magnetic device, according to an embodiment;

FIGS. 4A and 4B illustrate graphs of temporal changes of flow of a sputtering gas in a chamber during a manufacturing procedure of a magnetic device, according to embodiments;

FIGS. 5A and 5B illustrate graphs of properties of a tunnel magnetoresistance ratio (TMR) and critical current density (Jc) according to joint resistance (RA), according to embodiments;

FIG. 6 illustrates a cross-sectional view of a magnetic tunnel junction (MTJ) structure according to another embodiment;

FIGS. 7A through 7E illustrate sequentially-arranged cross-sectional views of a method of manufacturing a magnetic device, according to another embodiment;

FIGS. 8A through 8D illustrate graphs of a temporal change of flow of a sputtering gas in a chamber during a manufacturing process of a magnetic device, according to embodiments;

FIG. 9 illustrates a cross-sectional view of an MTJ structure according to another embodiment;

FIG. 10 illustrates a block diagram of an electronic system including magnetic devices according to embodiments;

FIG. 11 illustrates a block diagram of an information processing system including the magnetic devices according to embodiments; and

FIG. 12 illustrates a memory card including the magnetic devices according to some embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

While such terms as “first”, “second”, etc., may be used to describe various components, such components must not be limited to the above terms. The above terms are used only to distinguish one component from another.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section.

Unless otherwise defined, all terms (including technical and scientific terms) used herein have the same meaning as commonly understood by one of skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

When a certain embodiment may be implemented differently, a specific process order may be performed differently from the described order. For example, two consecutively described processes may be performed substantially at the same time or performed in an order opposite to the described order.

Variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

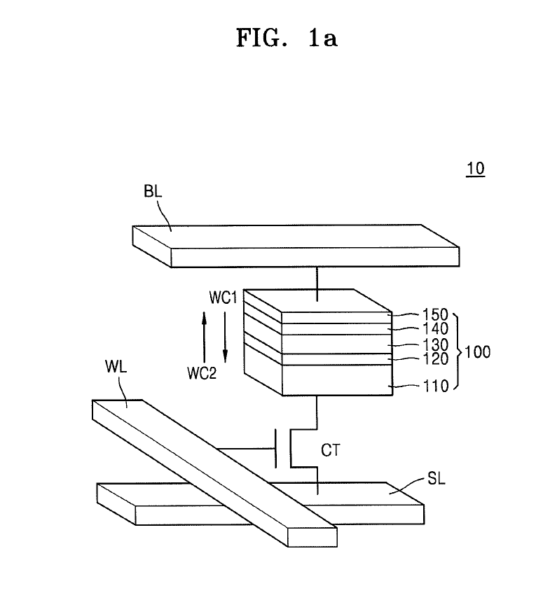

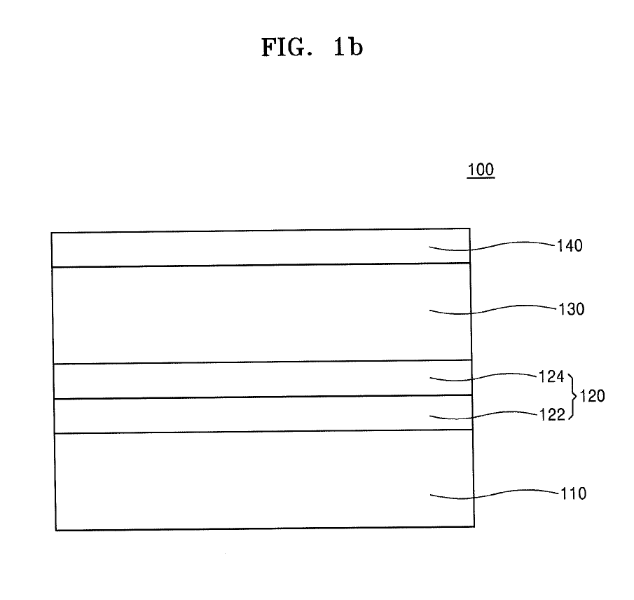

FIGS. 1A and 1B illustrate a magnetic device 10 according to an embodiment. FIG. 1A illustrates a schematic structure of the magnetic device 10. FIG. 1B illustrates a cross-sectional view of a magnetic tunnel junction (MTJ) structure 100 included in the magnetic device 10.

FIG. 1A illustrates the magnetic device 10 having a spin transfer torque magnetoresistive random access memory (STT-MRAM) structure. Referring to FIG. 1A, the magnetic device 10 may include the MTJ structure 100 and a cell transistor CT. A gate of the cell transistor CT may be connected to a word line WL. An electrode of the cell transistor CT may be connected to a bit line BL through the MTJ structure 100, and another electrode of the cell transistor CT may be connected to a source line SL.

The MTJ structure 100 may include a pinned layer 110, a free layer 130, a first insulating layer 120 interposed between the pinned layer 110 and the free layer 130, and a second insulating layer 140 formed on an upper surface of the free layer 130.

A capping layer 150 may be formed on the MTJ structure 100 and may function as an upper electrode in the magnetic device 10.

The pinned layer 110 may have a magnetization easy axis in a direction perpendicular to a surface of the pinned layer 110 and a fixed magnetization orientation. The free layer 130 may have a magnetization easy axis in a direction perpendicular to a surface of the free layer 130 and a magnetization orientation that is variable according to conditions.

A resistance of the MTJ structure 100 may change depending on the magnetization orientation of the free layer 130. When the magnetization orientation of the free layer 130 is parallel to the magnetization orientation of the pinned layer 110, the MTJ structure 100 may have a low resistance and may store a piece of data, ‘0’. When the magnetization orientation of the free layer 130 is anti-parallel to the magnetization orientation of the pinned layer 110, the MTJ structure 100 may have a high resistance and may store a piece of data, ‘1’. Exemplary locations of the pinned layer 110 and the free layer 130 are shown in FIG. 1A; the locations of the pinned layer 110 and the free layer 130 may be exchanged with each other.

In the magnetic device 10 of FIG. 1A, for the writing operation of the STT-MRAM, a voltage having a high logic level may be applied to the word line WL, the cell transistor CT may be turned on, and writing currents WC1 and WC2 may be applied between the bit line BL and a source line SL. According to orientations of the writing currents WC1 and WC2, the magnetization orientation of the free layer 130 may be determined. For example, when the writing current WC1 is applied, free electrons having the same spin as the pinned layer 110 may apply a torque to the free layer 130, and then the free layer 130 may be magnetized in the same direction as the pinned layer 110. When the writing current WC2 is applied, electrons having a spin opposite to that of the pinned layer 110 may return to the free layer 130 and apply a torque to the free layer 130, and then the free layer 130 may be magnetized in the opposite direction to the pinned layer 110. In the MTJ structure 100, the magnetization orientation of the free layer 130 may be changed by the STT.

In the magnetic device 10 of FIG. 1A, for a reading operation of the STT-MRAM, a voltage having a high logic level may be applied to the word line WL, the cell transistor CT may be turned on, a reading current may be applied in a direction from the bit line BL to the source line SL, and data stored in the MTJ structure 100 may be determined. Since an intensity of the reading current may be smaller, e.g., much smaller, than those of the writing currents WC1 and WC2, the magnetization orientation of the free layer 130 may not be changed by the reading current.

Referring to FIG. 1B, the MTJ structure 100 may include the pinned layer 110, the free layer 130, the first insulating layer 120 interposed between the pinned layer 110 and the free layer 130, and the second insulating layer 140 formed on the upper surface of the free layer 130.

In an embodiment, the MTJ structure 100 may have a structure in which the pinned layer 110 is stacked earlier than the free layer 130.

The pinned layer 110 and the free layer 130 may respectively have interface perpendicular magnetic anisotropy (IPMA) on interfaces (i.e., contact surfaces) of the first and second insulating layers 120 and 140.

The pinned layer 110 and the free layer 130 may be formed of ferromagnetic materials. The ferromagnetic materials may have a relatively high magnetic anisotropic energy (Ku) in a range from about 10⁶ to about 10⁷ erg/cc. The pinned layer 110 and the free layer 130 may have magnetization easy axes perpendicular to the interfaces, for example, due to the high magnetic anisotropic energy.

Hereinafter, the pinned layer 110 and the free layer 130 will be described in detail.

The pinned layer 110 may be a magnetic layer having a fixed magnetization orientation, and the ferromagnetic material forming the pinned layer 110 may include one or more of cobalt (Co), iron (Fe), or nickel (Ni). The ferromagnetic material may further include other elements such as boron (B), chromium (Cr), platinum (Pt), and palladium (Pd).

In an embodiment, the pinned layer 110 may be, for example, a single layer. As described below, the pinned layer 110 may have a multilayer structure.

In some embodiments, the pinned layer 110 may have a multilayer structure in which a first layer, which may be formed of, e.g., include, one or more of Co or a Co alloy, and a second layer, which may be formed of, e.g., include, one or more of Pt, Ni, or Pd, are alternately stacked, or may be a FePt layer or a CoPt layer having a L₁₀ structure. In an embodiment, the pinned layer 110 may be an alloyed layer of a rare-earth element and a transition metal. The rare-earth element may be one or more of terbium (Tb) or gadolinium (Gd), and the transition metal may be one or more of Ni, Fe, or Co. Alloys in which the rare-earth element and the transition metal are variously combined may be used, and for example, CoFeB or CoFe may be used to form the pinned layer 110.

In other embodiments, the pinned layer 110 may have a synthetic antiferromagnetic (SAF) structure in which two pinned layers (not shown) having magnetization orientations which are fixed in opposite directions and a spacer (not shown) interposed between the pinned layers are included. The pinned layers may be formed of the same ferromagnetic material, or may be formed of different ferromagnetic materials. For example, one of the pinned layers, which is adjacent to the first insulating layer 120, may include an Fe-based or CoFe-based material, for example, CoFeB, and the other of the pinned layers may include a Co-based material, for example, CoPt. The spacer (not shown) interposed between the pinned layers may include a conductive material, for example, one or more of ruthenium (RO, copper (Cu), aluminum (Al), gold (Au), silver (Ag), or combinations thereof. The pinned layers which are magnetized in opposite directions may mutually offset stray magnetic fields of each other, and an influence of a stray magnetic field generated in the pinned layer 110 on the free layer 130 may be controlled or prevented.

The free layer 130 may be a magnetic layer having a variable magnetization orientation. The free layer 130 may include a ferromagnetic material having a magnetic moment, which may have a magnetization orientation freely changing in a direction perpendicular to a floor, e.g., a bottom layer, for example, the ferromagnetic material may include one or more of Co, Fe, or Ni. Furthermore, the ferromagnetic material may include other elements such as B, Cr, Pt, and Pd. The free layer 130 may be formed of a different material from or the same material as that used to form the pinned layer 110.

The first insulating layer 120 may be interposed between the pinned layer 110 and the free layer 130, and a tunnel magnetoresistance ratio (TMR) of a MTJ structure 100 may be increased. The first insulating layer 120 may have a thickness ranging from about 8 Å to about 15 Å.

In an embodiment, the first insulating layer 120 may include a first lower insulating layer 122 formed on an upper surface of the pinned layer 110, and a first upper insulating layer 124 formed on an upper surface of first lower insulating layer 122.

The first lower insulating layer 122 and the first upper insulating layer 124 may include a non-magnetic material. The first lower insulating layer 122 and the first upper insulating layer 124 may be formed of, for example, a metal oxide including one or more of magnesium (Mg), Al, titanium (Ti), tantalum (Ta), hafnium (Hf), or zirconium (Zr). The first lower insulating layer 122 and the first upper insulating layer 124 may be formed of different metal oxides, or may be formed of the same metal oxide.

In some embodiments, the first lower insulating layer 122 and the first upper insulating layer 124 may be a single layer, respectively. In other embodiments, the first lower insulating layer 122 and the first upper insulating layer 124 may be multiple layers which include sequentially stacked layers. For example, each of the first lower insulating layer 122 and the first upper insulating layer 124 may have a multi-layer structure selected from magnesium/magnesium oxide (Mg/MgO), MgO/Mg, and Mg/MgO/Mg.

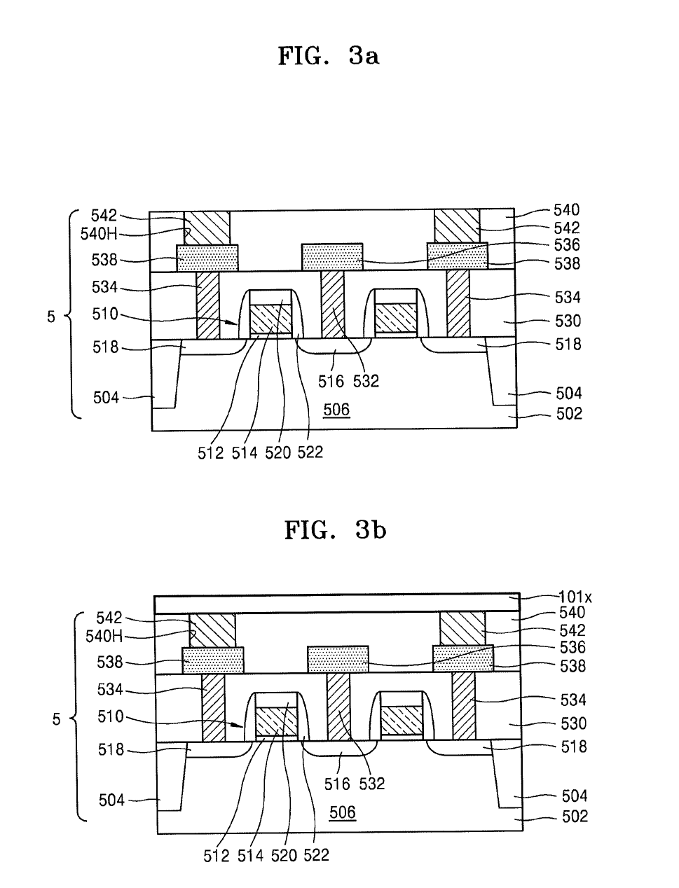

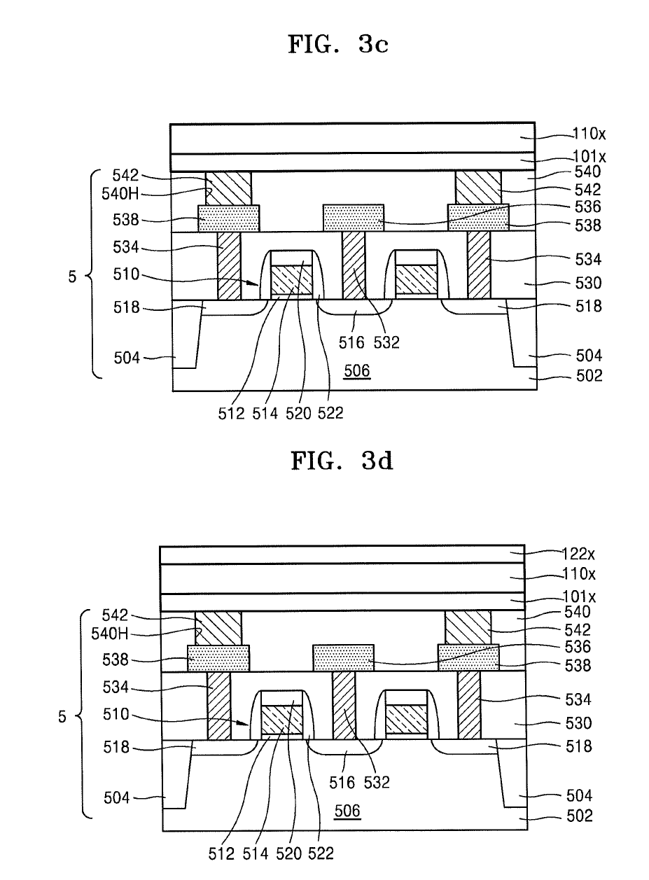

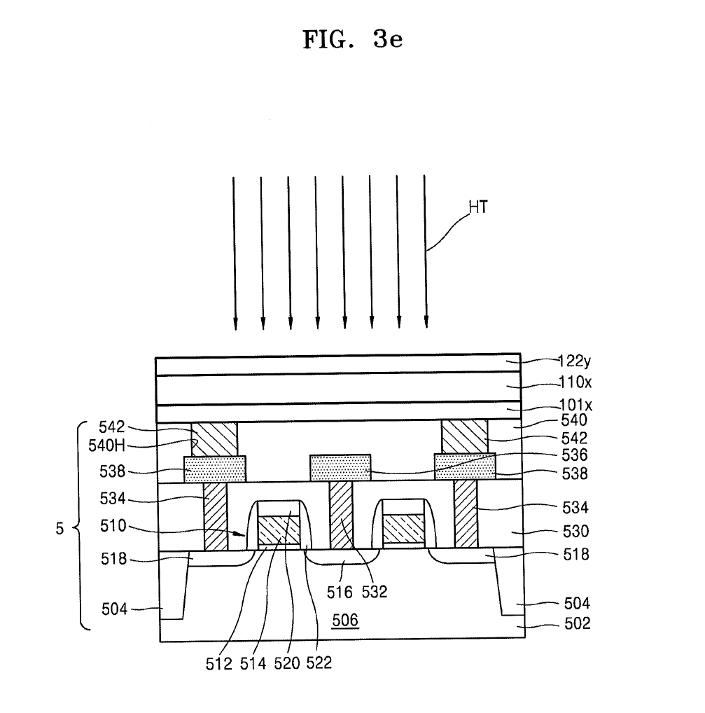

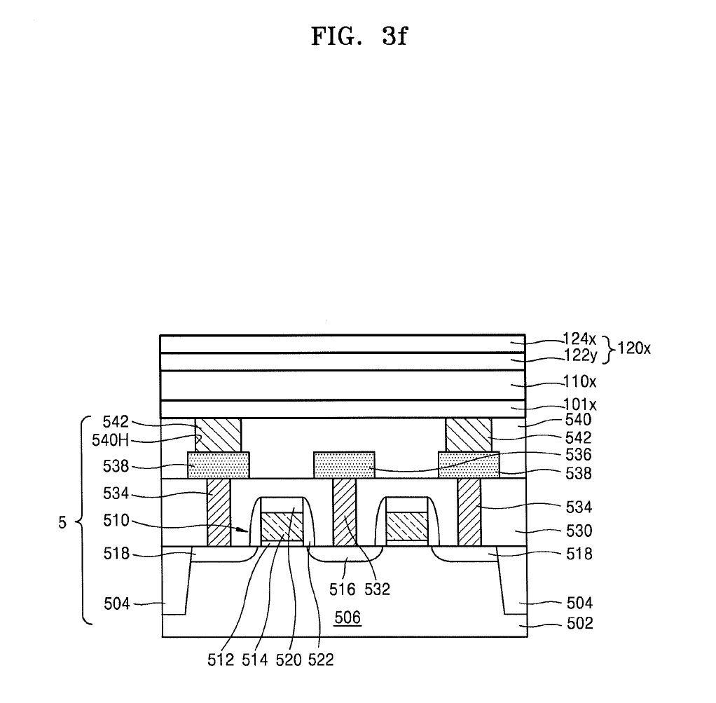

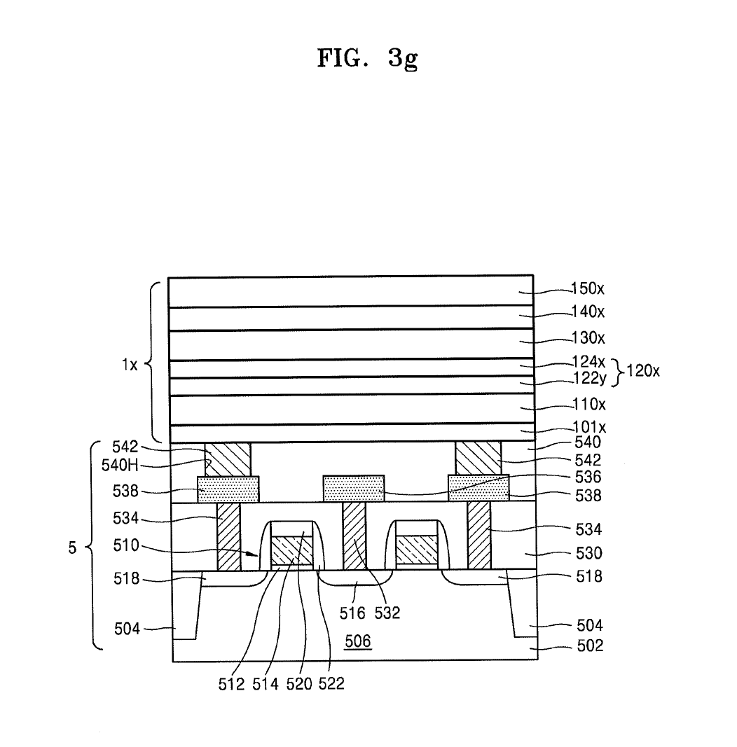

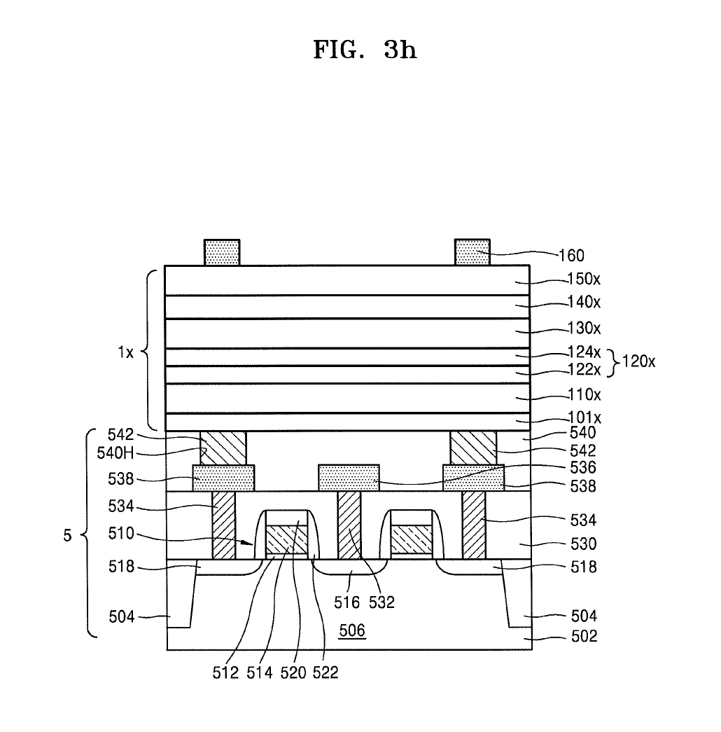

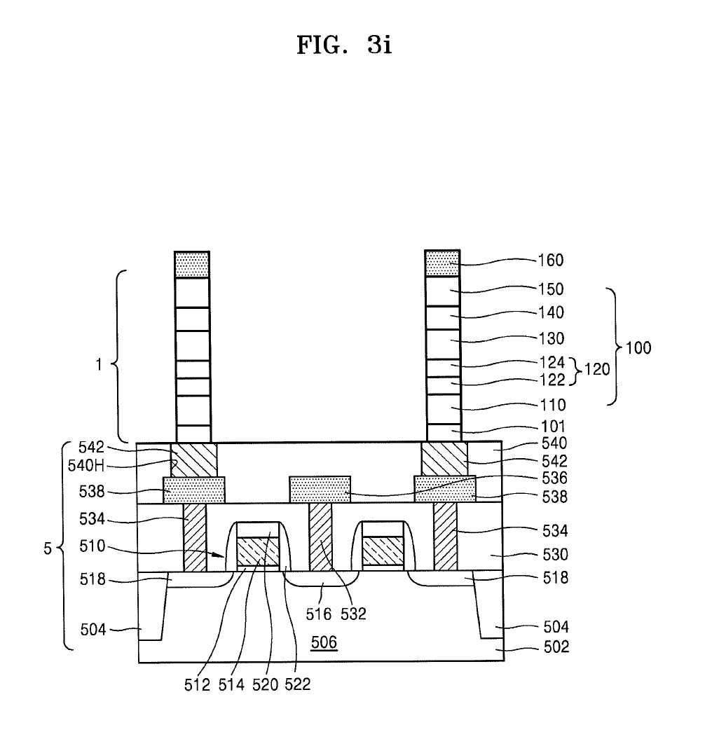

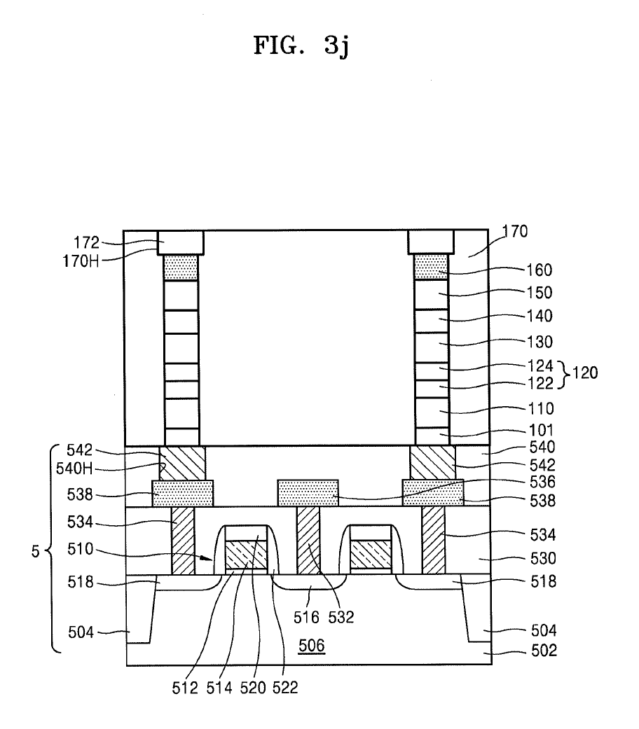

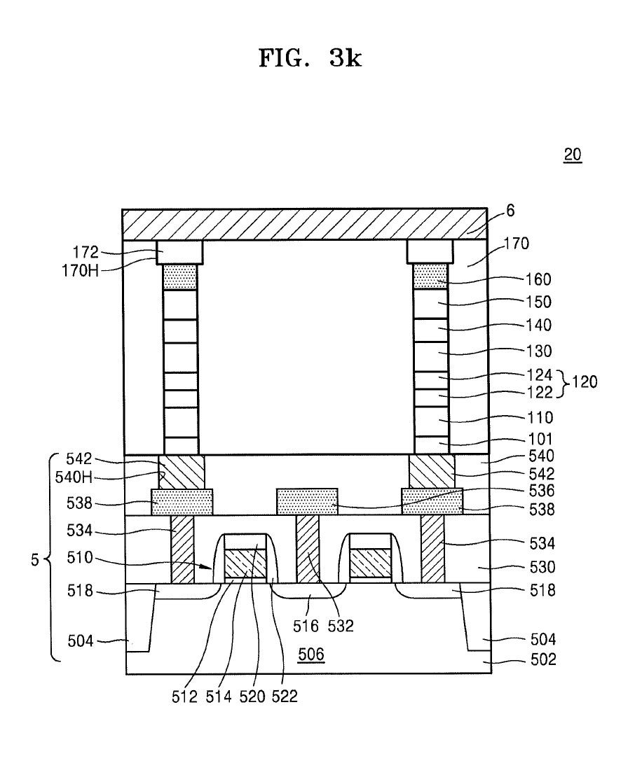

The first lower insulating layer 122 may be formed of, e.g., using, a sputtering gas, which may be an inert gas having an atomic weight greater than that of, for example, krypton (Kr) or argon (Ar). The first lower insulating layer 122 may have a thickness ranging from about 4 Å to about 8 Å. The first upper insulating layer 124 may be formed using a sputtering gas, which may be Ar gas. A detailed description of a method of forming the first insulating layer 120 will be provided later with reference to FIGS. 3A through 3K.

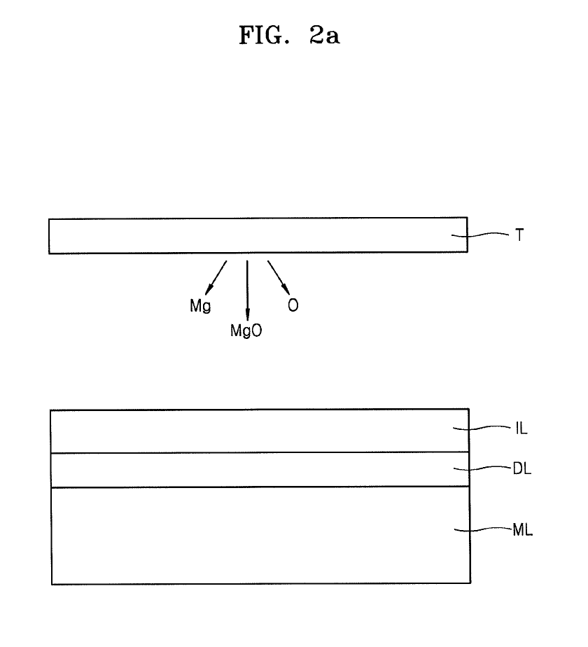

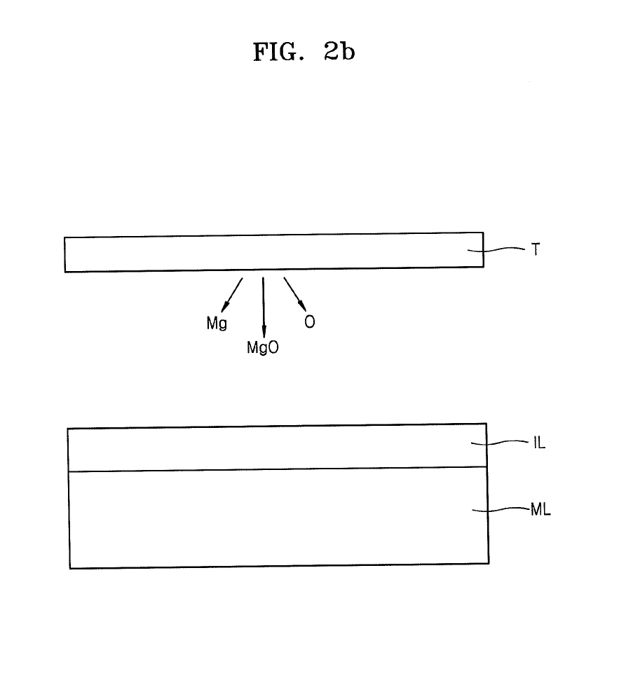

As described above, when the first lower insulating layer 122 is formed using an inert gas having an atomic weight greater than that of Ar, flow of the inert gas necessary for a sputtering process may be decreased, and an amount of oxygen radicals such as MgO, which may be emitted from a sputtering target, may be decreased. As a result, a property of an interface between the pinned layer 110 and the first insulating layer 120 may be improved (a detailed description thereof will be provided later with reference to FIGS. 2A and 2B).

The second insulating layer 140 may be formed on an upper surface of the free layer 130 and may strengthen IPMA of the free layer 130. The second insulating layer 140 may have a thickness ranging from about 4 Å to about 10 Å.

The second insulating layer 140 may include a non-magnetic material. Like the first insulating layer 120, the second insulating layer 140 may be formed of a metal oxide including one or more of Mg, Al, Ti, Ta, Hf, or Zr.

In some embodiments, the second insulating layer 140 may be a single layer. In other embodiments, the second insulating layer 140 may be multiple layers which include sequentially stacked layers. For example, the second insulating layer 140 may have a multi-layer structure selected from Mg/MgO, MgO/Mg, and Mg/MgO/Mg.

The second insulating layer 140 may be formed of metal oxides different from or the same as that used to form the first insulating layer 120.

In some embodiments, like the first lower insulating layer 122, the second insulating layer 140 may be formed using a sputtering gas, which may be an inert gas having a greater atomic weight than, for example, Kr or Ar. In other embodiments, like the first lower insulating layer 122, the second insulating layer 140 may be formed using a sputtering gas, which may be Ar gas.

Like the first lower insulating layer 122, the second insulating layer 140 may be divided into two layers. Like the first lower insulating layer 122, a lower surface of the second insulating layer 140 may be formed using an inert gas having a greater atomic weight than Ar, and an upper surface of the second insulating layer 140 may be formed using Ar gas.

In some embodiments, the pinned layer 110, the first insulating layer 120, the free layer 130, and the second insulating layer 140 may have the same crystal structure. For example, each of the pinned layer 110, the first insulating layer 120, the free layer 130, and the second insulating layer 140 may have a body centered cubic (BCC) crystal structure.

FIGS. 2A and 2B illustrate conceptual views for explaining a principle which improves an operational property of a magnetic device, according to embodiments. FIG. 2A illustrates a sputtering process in which Ar gas is used as a sputtering gas, and FIG. 2B illustrates a sputtering process in which an inert gas having a greater atomic weight than Ar is used as a sputtering gas.

In the present embodiment, a magnetic layer ML may be the pinned layer 110 or the free layer 130 described with reference to FIG. 1B. An insulating layer IL of the present embodiment may be the first insulating layer 120 or the second insulating layer 140 described with reference to FIG. 1B.

As described above with reference to FIG. 1B, the magnetic layer ML and the insulating layer IL may have a variety of composition and layer structures, but hereinafter, a case where the magnetic layer ML contains a CoFe-based material, and the insulating layer IL contains MgO will be described for convenience.

Referring to FIGS. 2A and 2B, a sputtering process in which a metal oxide such as MgO is used as a sputtering target T may be performed to form the insulating layer IL on the magnetic layer ML.

The insulating layer IL may be formed when MgO molecules emitted from the target T formed of MgO are attached onto the magnetic layer ML.

During the sputtering process, Mg and oxygen (O) atoms (or molecules) other than the MgO molecules may be emitted from the target T, and some of the emitted 0 atoms include oxygen radicals having a high reactivity.

According to the method of forming the insulating layer IL, an inert gas having a greater atomic weight than Ar may be used as a sputtering gas, flow of the sputtering gas necessary during the sputtering process may be decreased, and an amount of the oxygen radicals emitted from the target T may be decreased.

The oxygen radicals emitted from the target T may react with, for example, Fe, included in the magnetic layer ML, a damage layer DL containing, for example, FeO, may be formed, and deterioration of the crystal structure of the insulating layer IL and deterioration of the IPMA of the magnetic layer ML may be reduced or controlled.

FIGS. 3A through 3K illustrate sequentially arranged cross-sectional views of a method of manufacturing a magnetic device 20 (refer to FIG. 3K), according to an embodiment. In the present embodiment, a process of manufacturing an STT-MRAM device including the MTJ structure 100 described with reference to FIG. 1B will be described. When FIGS. 3A through 3K are compared with FIGS. 1A and 1B, like reference numerals in the drawings denote like elements, and for convenience, detailed descriptions thereof will be omitted.

Each of a pinned layer 110x, a first insulating layer 120x, a free layer 130x, and a second insulating layer 140x to be described below may have similar structures to the structure of each of the pinned layer 110, the first insulating layer 120, the free layer 130, and the second insulating layer 140 described with reference to FIG. 1B.

A lower electrode layer 101x, the pinned layer 110x, the first insulating layer 120x, the free layer 130x, the second insulating layer 140x, and a capping layer 150x may form a stack structure to be described with reference to FIG. 3K before an etching process is performed.

FIG. 3A illustrates a lower structure 5 of the magnetic device 20 (refer to FIG. 3K). Referring to FIG. 3A, the lower structure 5 may include a transistor 510 formed on an active region 506. The active region 506 may be defined by a device isolating layer 504 formed in a substrate 502.

In some embodiments, the substrate 502 may be a semiconductor wafer. The substrate 502 may include silicon (Si). In other embodiments, the substrate 502 may include a semiconductor element such as germanium (Ge) or a compound semiconductor such as silicon carbide (SiC), gallium arsenide (GaAs), indium arsenide (InAs), and indium phosphide (InP). In other embodiments, the substrate 502 may have a silicon-on-insulator (SOI) structure. For example, the substrate 502 may include a buried oxide (BOX) layer. In some embodiments, the substrate 502 may include a conductive region, for example, a well doped with impurities or a structure doped with impurities. The device isolating layer 504 may have a shallow trench isolation (STI) structure.

The transistor 510 may include a gate insulating layer 512, a gate electrode 514, a source region 516, and a drain region 518. The gate electrode 514 may have an upper surface and sides which may respectively be insulated by an insulating capping pattern 520 and an insulating spacer 522.

Then, a first interlayer insulating layer 530, which may be planarized and cover the transistor 510, may be formed on the substrate 502, and first contact plugs 532 which penetrate the first interlayer insulating layer 530 and are electrically connected to a source region 516 may be formed. A second contact plug 534, which may be electrically connected to a drain region 518, may be formed. After a conductive layer is formed on the first interlayer insulating layer 530, the conductive layer may be patterned. A source line 536, which may be electrically connected to a source region 516 through the first contact plugs 532, and conductive patterns 538, which may be electrically connected to drain regions 518 through second contact plugs 534 at both sides of the source line 536, may be formed.

Then, a second interlayer insulating layer 540 may be formed on the first interlayer insulating layer 530, and the source line 536 and the conductive patterns 538 may be covered. Through a photolithography process, some portions of the second interlayer insulating layer 540 may be removed, upper surfaces of the conductive patterns 538 may be exposed, and then a lower electrode contact hole 540H may be formed. The lower electrode contact hole 540H may be filled with a conductive material, the conductive material may be polished, an upper surface of the second interlayer insulating layer 540 may be exposed, and lower electrode contact plugs 542 may be formed. In some embodiments, the lower electrode contact plugs 542 may include one or more of TiN, Ti, TaN, Ta, or tungsten (W).

Referring to FIG. 3B, the lower electrode layer 101x may be formed on the lower structure 5. In some embodiments, the lower electrode layer 101x may be formed of a metal or a metal nitride. For example, the lower electrode layer 101x may be formed of TiN. The lower electrode layer 101x may be formed through a chemical vapor deposition (CVD) process, a physical vapor deposition (PVD) process, an atomic layer deposition (ALD) process, or a reactive pulsed laser deposition (reactive PLD) process.

Referring to FIG. 3C, the pinned layer 110x may be formed on the lower electrode layer 101x. The pinned layer 110x may have a similar stack structure to that of the pinned layer 110 described with reference to FIG. 1B. In an embodiment, the pinned layer 110x is a single layer, but as described with reference to FIG. 1B, the pinned layer 110x may have a multilayer structure.

The pinned layer 110x, may be formed through, for example, a molecular beam epitaxy (MBE) process, a metal organic CVD (MOCVD) process, a DC sputtering process, an RF sputtering process, an ion beam sputtering process, a magnetron sputtering process, or an ultra-high vacuum (UHV) sputtering process.

Although not illustrated, before the pinned layer 110x is formed, a seed layer (not shown) may be further formed, wherein the seed layer is used to change crystallographic textures of the pinned layer 110x and layers formed after the pinned layer 110x to desired crystallographic textures. The seed layer may include, for example, a ruthenium (Ru) layer. The seed layer may be formed through a CVD process, a PVD process, an ALD process, or a reactive PLD process.

Referring to FIG. 3D, the first lower insulating layer 122x may be formed on the pinned layer 110x. The first lower insulating layer 122x may include a non-magnetic material. The first lower insulating layer 122x may be formed of a metal oxide including one or more of Mg, Al, Ti, Ta, Hf, or Zr. Hereinafter, a case where the first lower insulating layer 122x is formed of MgO will be described for convenience.

The first lower insulating layer 122x may be formed through, for example, a DC sputtering process, an RF sputtering process, an ion beam sputtering process, a magnetron sputtering process, or an UHV sputtering process.

The first lower insulating layer 122x may be formed through a sputtering process in which a metal oxide such as MgO is a sputtering target. The first lower insulating layer 122x may have a thickness ranging from about 4 Å to about 8 Å.

In other embodiments, the first lower insulating layer 122x may use a metal such as Mg as a sputtering target and may be formed through a sputtering process, which may be performed in an atmosphere in which oxygen and an inert gas are mixed. After the sputtering process in which the metal such as Mg is used as the sputtering target is performed, the first lower insulating layer 122x may be formed by further performing a process in which a metal layer formed of a metal such as Mg is oxidized.

The first lower insulating layer 122x may be formed by using a sputtering gas, which may be an inert gas having a greater atomic weight than Ar. For example, the sputtering gas forming the first lower insulating layer 122x may include one or more of Kr, xenon (Xe), or radon (Rn).

While the first lower insulating layer 122x is formed, flow of the sputtering gas within a reaction chamber may be from about 1 to about 50 cm³/min. Pressure in the reaction chamber may be from about 0.001 to about 0.1 mTorr.

When the first lower insulating layer 122x is formed by using an inert gas having an greater atomic weight than Ar, flow of the inert gas required for the sputtering process may be decreased, the amount of oxygen radicals which may be generated in the reaction chamber may be decreased, and formation of the damage layer DL (refer to FIGS. 2A and 2B) formed of, for example, FeO, on an interface between the first insulating layer 320x and the pinned layer 110x may be reduced or controlled.

Referring to FIG. 3E, a heat treatment (HT) process may be performed on a stack structure including the first lower insulating layer 122x. The first lower insulating layer 122x may denote an amorphous MgO layer that may exist before the HT process is performed, and a first lower insulating layer 122y may be a crystalline MgO layer that may be formed after the HT process is performed.

The HT process may include: a first HT process for removing the damage layer DL (refer to FIGS. 2A and 2B) which may be formed on an interface between the pinned layer 110x and the first lower insulating layer 122x; and a second HT process for crystallizing the first lower insulating layer 122x at a temperature higher than a temperature of the first HT process.

In the present embodiment, the HT process may be performed after the first lower insulating layer 122x is formed but before the first upper insulating layer 124x (refer to FIG. 3F) is formed. In an embodiment, first and second HT processes may be performed. In other embodiments, the HT process may be performed after the first lower insulating layer 122x and the first upper insulating layer 124x (refer to FIG. 3F) are formed. In other embodiments, the first HT process may be performed after the first lower insulating layer 122x is formed, and the second HT process may be performed after the first upper insulating layer 124x is formed.

The first HT process may remove the damage layer DL (refer to FIGS. 2A and 2B), which may be formed on the interface between the pinned layer 110x and the first lower insulating layer 122x, and may be performed at a temperature ranging from about 50° C. to about 150° C.

When the first HT process is performed on the stack structure including the first lower insulating layer 122x, oxygen atoms may be moved from the damage layer DL to the first lower insulating layer 122x, wherein the oxygen atoms exist in the damage layer DL (refer to FIGS. 2A and 2B), which contains, for example, FeO, and may be formed on the interface between the pinned layer 110x and the first lower insulating layer 122x while the first lower insulating layer 122x is formed. Then, the damage layer DL which may negatively affect properties of the interface between the pinned layer 110x and the first lower insulating layer 122x may be reduced or removed.

The second HT process may be performed to change the first lower insulating layer 122x to the crystalline first lower insulating layer 122y.

The second HT process may be performed at a temperature higher than that of the first HT process, for example, at a temperature ranging from about 100° C. to about 400° C.

The first lower insulating layer 122y on which the second HT process is performed may have, for example, a BCC crystal structure.

After the first lower insulating layer 122x is formed as described above, the initial crystallinity of the first insulating layer 120x (refer to FIG. 3F) may be secured by performing the second HT process before the first upper insulating layer 124x (refer to FIG. 3F) is formed.

In some embodiments, the first HT process and the second HT process may be respectively performed as a process in which the first lower insulating layer 122x is formed and then the first lower insulating layer 122x is formed and as an in-situ method.

Referring to FIG. 3F, the first upper insulating layer 124x may be formed on the first lower insulating layer 122y, and the first insulating layer 120x may be completed. The first insulating layer 120x may have a thickness ranging from about 8 Å to about 15 Å.

The first upper insulating layer 124x may include a non-magnetic material like the first lower insulating layer 122y. The first upper insulating layer 124x may be formed of a metal oxide including one or more of Mg, Al, Ti, Ta, Hf, or Zr. The first lower insulating layer 122y and the first upper insulating layer 124x may be formed of different metal oxides, or may be formed of the same metal oxide. Hereinafter, a case where the first upper insulating layer 124x is formed of MgO will be described for convenience.

In some embodiments, the first upper insulating layer 124x may be formed through a sputtering process in which the metal oxide such as Mg is used as a sputtering target. In other embodiments, the first upper insulating layer 124x may use a metal such as Mg as a sputtering target and may be formed in an atmosphere in which oxygen and an inert gas are mixed. The first upper insulating layer 124x may be formed by performing a sputtering process in which the metal oxide such as Mg is used as a sputtering target and separately performing a process in which a metal layer including the metal oxide such as Mg is oxidized.

The first upper insulating layer 124x may be formed by using a sputtering gas, which may be Ar gas. While the first upper insulating layer 124x is formed, flow of the sputtering gas within the reaction chamber may be from about 50 to about 150 cm³/min. Pressure in the reaction chamber may be from about 0.1 to about 1 mTorr.

Referring to FIG. 3G, the free layer 130x, the second insulating layer 140x, and the capping layer 150x may sequentially be formed on the first insulating layer 120x. In the stack structure 1x, exemplary locations of the pinned layer 110x and the free layer 130x are shown in FIG. 3G; the locations of the pinned layer 110x and the free layer 130x may be exchanged with each other. In an exemplary embodiment, the stack structure 1x includes the lower electrode layer 101x to the capping layer 150x sequentially stacked as shown. According to desired properties of the magnetic device, various types of layers may be added or replaced in the stack structure 1x.

The free layer 130x and the second insulating layer 140x may have similar structures to those of the free layer 130 and the second insulating layer 140 described with reference to FIG. 1B.

The free layer 130x may be formed through, for example, an MBE process, an MOCVD process, or a sputtering process.

In some embodiments, like the first lower insulating layer 122x, the second insulating layer 140x may be formed by using a sputtering gas, which may be an inert gas having an greater atomic weight than, for example, Kr or Ar. In other embodiments, like the first lower insulating layer 122x, the second insulating layer 140x may be formed by using a sputtering gas, which may be Ar gas.

Like the first lower insulating layer 122x, the second insulating layer 140x may be divided into two layers. For example, like the first lower insulating layer 122x, a lower surface of the second insulating layer 140x may be formed by using an inert gas having a greater atomic weight than Ar, and an upper surface of the second insulating layer 140x may be formed by using a sputtering gas, which may be Ar gas. The second insulating layer 140x may have a thickness ranging from about 4 Å to about 10 Å.

Although not illustrated, after the second insulating layer 140x is formed, a third heat treatment process may be further performed on the stack structure including the second insulating layer 140x.

The third heat treatment process may reduce or remove the damage layer DL (refer to FIGS. 2A and 2B), which may be formed on an interface between the free layer 130x and the second insulating layer 140x. The third heat treatment process may be formed at a temperature ranging from about 50° C. to about 150° C.

When the third heat treatment process is performed on the stack structure including second insulating layer 140x, oxygen atoms in the damage layer DL (refer to FIGS. 2A and 2B), which may be formed of, for example, FeO, and may be formed on the interface between the free layer 130x and the second insulating layer 140x while the second insulating layer 140x is formed, may be moved from the damage layer DL to the second insulating layer 140x, and the damage layer DL which may negatively affect a property of the interface between the free layer 130x and the second insulating layer 140x may be decreased or removed.

In some embodiments, after the second insulating layer 140x is formed, the third heat treatment process may be performed in an in-situ manner. In some embodiments, the third heat treatment process may be performed in an in-situ manner after the second insulating layer 140x is formed.

The capping layer 150x may include one or more of Ta, Al, Cu, Au, Ti, TaN, or TiN.

Referring to FIG. 3H, multiple conductive mask patterns 160 may be formed on the stack structure 1x.

The conductive mask patterns 160 may be formed of a metal or a metal nitride. In some embodiments, the conductive mask patterns 160 may include one or more of Ru, W, TiN, TaN, Ti, Ta, or a metallic glass alloy. For example, the conductive mask patterns 160 may have a double-layer structure formed of Ru/TiN or TiN/W. The conductive mask patterns 160 may be formed to be on the same axis as that of the lower electrode contact plugs 542.

Referring to FIG. 3I, the conductive mask patterns 160 may be used as an etching mask, and the stack structure 1x may be etched.

To etch the stack structure 1x, a device including the conductive mask patterns 160 may be loaded in a plasma etching chamber, and then a plasma etching process may be performed. In some embodiments, a reactive ion etching (RIE) process, an ion beam etching (IBE) process, or an Ar milling process may be performed to etch the stack structure 1x. A first etching gas formed of, e.g., including, SF₆, NF₃, SiF₄, CF₄, Cl₂, CH₃OH, CH₄, CO, NH₃, H₂, N₂, HBr, or combinations thereof may be used to etch the stack structure 1x. In other embodiments, when the stack structure 1x is etched, a first additional gas formed of one or more of Ne, Ar, Kr, or Xe may be used in addition to the first etching gas.

The etching process of the stack structure 1x may be performed by using plasma formed from an inductively coupled plasma (ICP) source, a capacitively coupled plasma (CCP) source, an electron cyclotron resonance (ECR) plasma source, a helicon-wave excited plasma (HWEP) source, or an adaptively coupled plasma (ACP) source.

The etching process of the stack structure 1x may further include an etching process in which a second etching gas having a different composition from the first etching gas is used. The second etching gas may be formed of SF₆, NF₃, SiF₄, CF₄, Cl₂, CH₃OH, CH₄, CO, NH₃, H₂, N₂, HBr, or combinations thereof. In some embodiments, when the etching process in which the second etching gas is used is performed, a second additional gas formed of, e.g., including, one or more of Ne, Ar, Kr, or Xe may be further used.

The etching process of the stack structure 1x may be performed at a temperature ranging from about −10° C. to about 65° C. and at a pressure ranging from about 2 to about 5 mTorr. While the etching process of the stack structure 1x is performed, some portions of upper surfaces of the conductive mask patterns 160 may be polished, for example, due to an etching atmosphere, and heights of the conductive mask patterns 160 may be decreased.

Although not illustrated, the lower electrode layer 101x may be divided into lower electrodes 101 after the stack structure 1x is etched, and then an upper surface of the second interlayer insulating layer 540, which may be exposed, may be etched to a predetermined thickness.

After the stack structure 1x is etched, magnetoresistors 1, which may be formed of structures generated after the stack structure 1x is formed, may be formed on the lower electrode contact plugs 542. In the magnetoresistors 1, remaining portions of the conductive mask patterns 160 and the capping layer 150 may function as upper electrodes.

Referring to FIG. 3J, a third interlayer insulating layer 170, which may cover the magnetoresistors 1 and may be planarized, may be formed, bit-line contact holes 170H may be formed by etching and removing some portions of the third interlayer insulating layer 170, and the upper surfaces of the conductive mask patterns 160 forming the magnetoresistors 1 may be exposed.

Then, after conductive layers which fill insides of the bit-line contact holes 170H are formed, the conductive layers may be polished or etched-back until an upper surface of the third interlayer insulating layer 170 is exposed, and the bit-line contact plugs 172 may be formed in the bit-line contact holes 170H.

Referring to FIG. 3K, a conductive layer may be formed on the third interlayer insulating layer 170 and the bit-line contact plugs 172 and may be patterned, and the magnetic device 20 may be completed by forming a bit line 6 which may be electrically connected to the bit-line contact plugs 172.

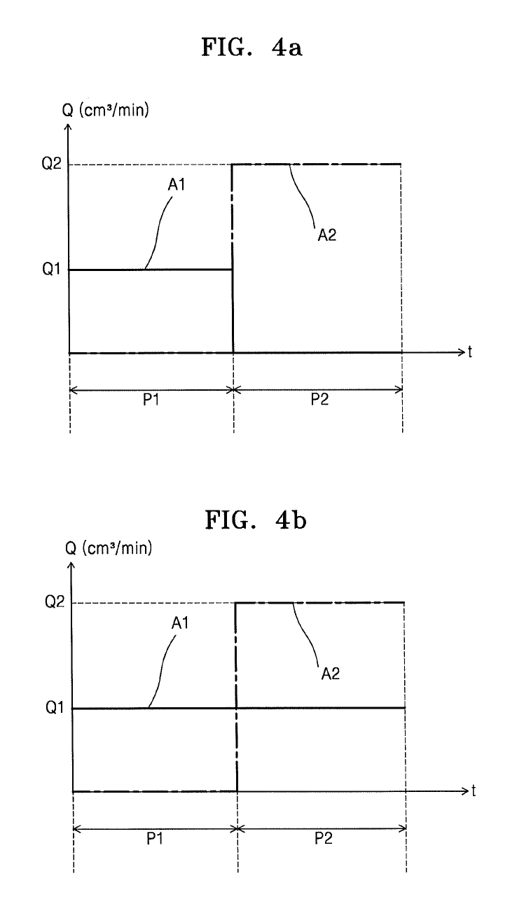

FIGS. 4A and 4B illustrate graphs of temporal changes of flow of a sputtering gas in a chamber during a manufacturing procedure of a magnetic device, according to embodiments. When descriptions regarding FIGS. 4A and 4B are provided, some components of FIGS. 3A through 3K may be referred to, and descriptions regarding the components will be provided with reference to FIGS. 3A through 4B. In FIGS. 4A and 4B, an X axis indicates time (t), and a Y axis indicates flow (Q) of a sputtering gas.

Referring to FIG. 4A, a first process P1 for forming the first lower insulating layer 122x and a second process P2 for forming the first upper insulating layer 124x may sequentially be performed. As described with reference to FIGS. 3A through 3K, the HT process may be performed between the first process P1 and the second process P2, but in the present embodiment, flow of a sputtering gas during the first process P1 and the second process P2 will only be described.

In the first process, a first gas A1 may be used as a sputtering gas. The first gas A1 may include an inert gas having a greater atomic weight than Ar. For example, the first gas A1 may include one or more of Kr, Xe, or Rn. While the first process is performed, flow Q1 of the first gas A1 may range from about 1 to about 50 cm³/min.

After the first process P1 is completed, the second process P2 for forming the first upper insulating layer 124x may be performed.

In the second process P2, a second gas A2 may be used as a sputtering gas. The second gas A2 may be, for example, Ar gas. While the second process P2 is performed, flow Q2 of the second gas A2 may range from about 50 to about 150 cm³/min.

Referring to FIG. 4B, the first gas A1 exists in the chamber while the second process P2 is performed unlike the second process P2 of FIG. 4A. As described with reference to FIG. 4A, the first gas A1 is discharged through an air pump (not shown), and then the second gas A2 may be injected so as to perform the second process P2. In an embodiment, as described with reference to FIG. 4B, the first gas A1 may not be discharged, and the second gas A2 may be additionally injected so as to perform the second process P2.

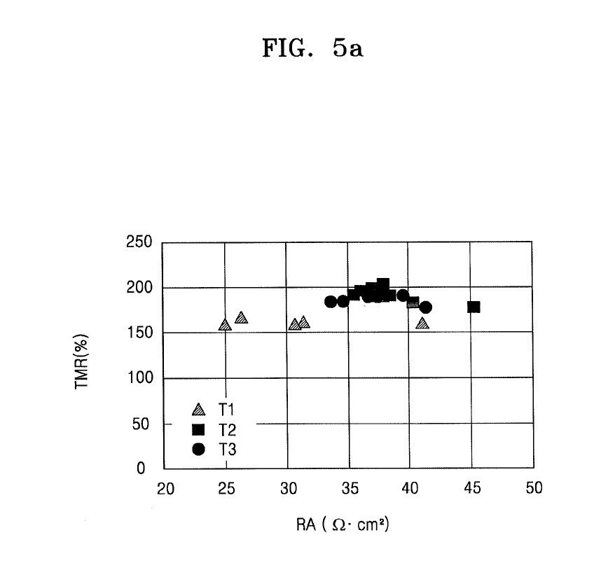

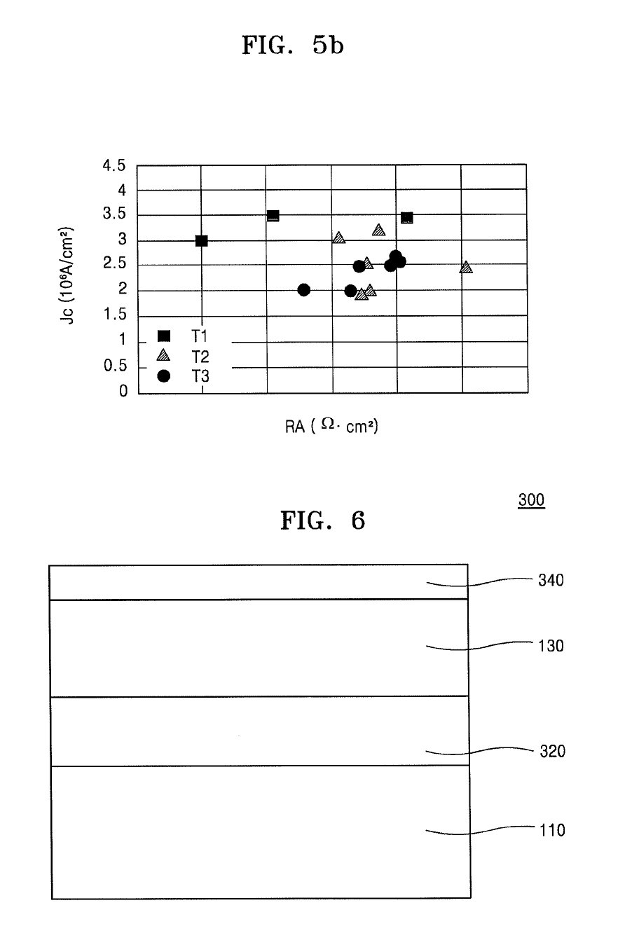

FIGS. 5A and 5B illustrate graphs of properties of a tunnel magnetoresistance ratio (TMR) and critical current density (Jc) according to joint resistance (RA), according to embodiments. When descriptions regarding FIGS. 5A and 5B are provided, some components of FIGS. 3A through 3K may be referred to, and descriptions regarding the components will be provided with reference to FIGS. 3A through 3K.

In FIGS. 5A and 5B, conditions other than a condition for forming the first insulating layer 120x and the second insulating layer 140x are the same in the manufacture of a magnetic device. In FIGS. 5A and 5B, the reference numeral “T1” indicates a case where Ar gas is used to form the first insulating layer 120x and the second insulating layer 140x.

The reference numeral “T2” indicates a case where the first insulating layer 120x is formed through a process in which the first lower insulating layer 122x is formed using Kr gas and a process in which the first upper insulating layer 124x is formed using Ar gas, and the second insulating layer 140x is formed using Ar gas.

The reference numeral “T3” indicates a case where the first insulating layer 120x is formed through a process in which the first lower insulating layer 122x is formed using Kr gas and a process in which the first upper insulating layer 124x is formed using Ar gas, and the second insulating layer 140x is formed using Kr gas.

According to FIG. 5A, that TMRs of “T2” or “T3” is about 20% greater than a TMR of “T1”. When the first insulating layer 120x having the first lower insulating layer 122x formed using Kr gas and the first upper insulating layer 124x formed using Ar gas is formed, a TMR of the magnetic device is increased.

According to FIG. 5B, the Jc of “T3” is about 1×10⁶ A/cm² smaller than that of “T1”. When the first insulating layer 120x having the first lower insulating layer 122x formed using Kr gas and the first upper insulating layer 124x formed using Ar gas is formed, and when the second insulating layer 140x is formed using Kr gas, the Jc of the magnetic device is decreased.

FIG. 6 illustrates a cross-sectional view of an MTJ structure 300 according to another embodiment. When FIG. 6 is compared with FIGS. 1A through 5B, like reference numerals in the drawings denote like elements, and repeated descriptions thereof will be omitted for convenience.

Referring to FIG. 6, the MTJ structure 300 may include a pinned layer 110, a free layer 130, a first insulating layer 320 interposed between the pinned layer 110 and the free layer 130, and a second insulating layer 340 formed on an upper surface of the free layer 130.

In an embodiment, the MTJ structure 300 may have a stack structure in which the pinned layer 110 is stacked earlier than the free layer 130.

The first insulating layer 320 may be interposed between the pinned layer 110 and the free layer 130, and a TMR of the MTJ structure 300 may be increased. The first insulating layer 320 may have a thickness ranging from about 8 Å to about 15 Å.

Like the first insulating layer 120 described with reference to FIG. 1B, the first insulating layer 320 may include a non-magnetic material. The first insulating layer 320 may be formed of, for example, a metal oxide including one or more of Mg, Al, Ti, Ta, Hf, or Zr.

In some embodiments, the first insulating layer 320 may be a single layer. In other embodiments, the first insulating layer 320 may be multiple layers including sequentially stacked layers. For example, the first insulating layer 320 may have a multi-layer structure selected from Mg/MgO, MgO/Mg, and Mg/MgO/Mg.

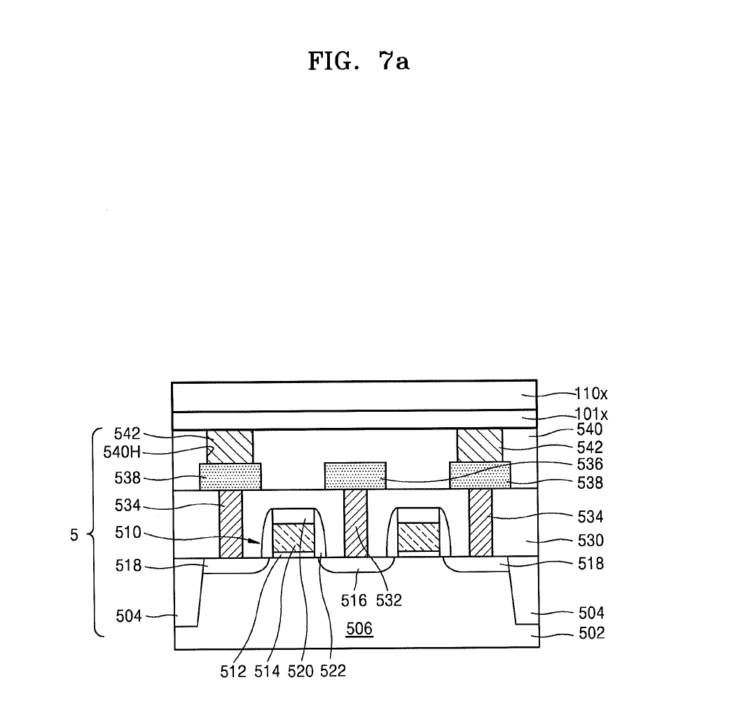

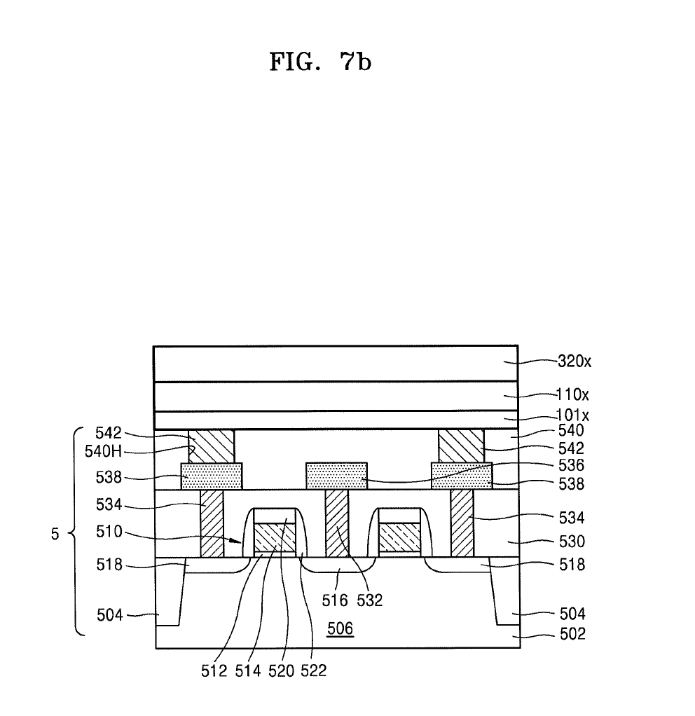

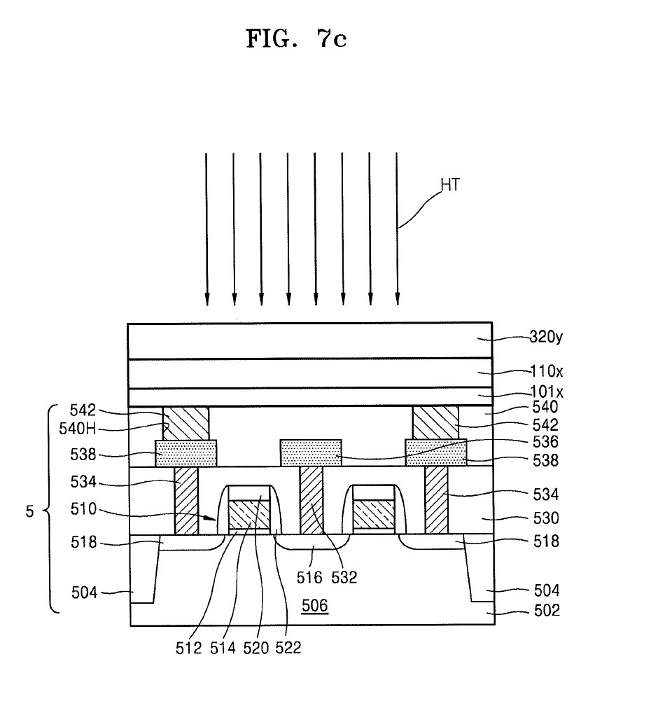

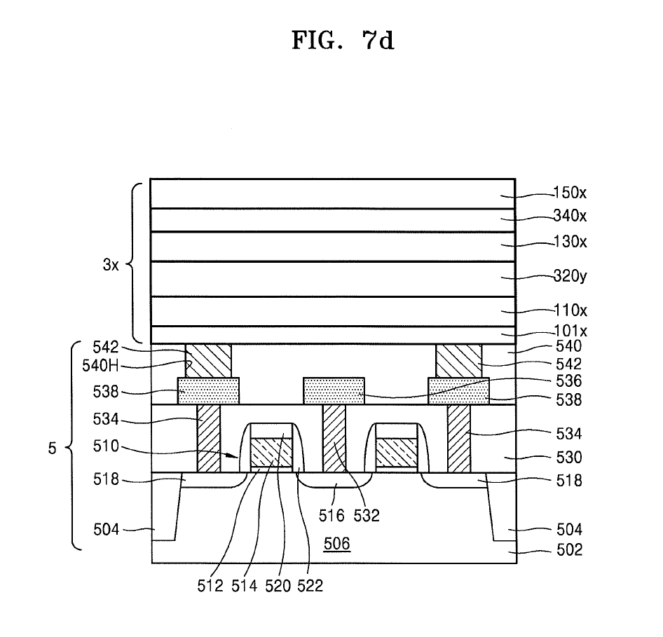

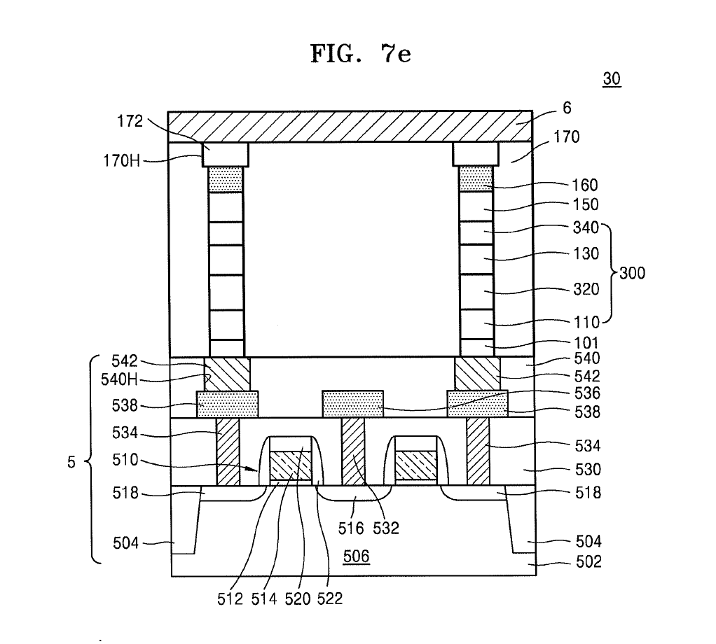

The first insulating layer 320 may be formed by using a gas mixture in which a first gas and a second gas are mixed (a detailed description regarding the gas will be provided later with reference to FIGS. 7A through 7E).

The second insulating layer 340 may be formed on the upper surface of the free layer 130 and may reinforce IPMA of the free layer 130. The second insulating layer 340 may have a thickness ranging from about 4 Å to about 10 Å.

Like the second insulating layer 140 described with reference to FIG. 1B, the second insulating layer 340 may include a non-magnetic material. The second insulating layer 340 may be formed of, for example, a metal oxide including one or more of Mg, Al, Ti, Ta, Hf, or Zr. The second insulating layer 340 may be formed of a different material from or the same material as that used to form the first insulating layer 320.

In some embodiments, like the first insulating layer 320, the second insulating layer 340 may be formed using the gas mixture in which the first gas and the second gas are mixed.

FIGS. 7A through 7E illustrate sequentially-arranged cross-sectional views of a method of manufacturing a magnetic device 30 (refer to FIG. 7E), according to another embodiment. In the present embodiment, a manufacturing process via which a STT-MRAM device including the MTJ structure 300 described with reference to FIG. 6 is manufactured will be described. When FIGS. 7A through 7E are compared with FIGS. 1A through 6, like reference numerals in the drawings denote like elements, and repeated descriptions thereof will be omitted for convenience.

Each of a pinned layer 110x, a first insulating layer 320x, a free layer 130x, and a second insulating layer 340x to be described below may have a similar structure to each of the pinned layer 110, the first insulating layer 320, the free layer 130, and the second insulating layer 340 described with reference to FIG. 6.

A lower electrode layer 101x, the pinned layer 110x, the first insulating layer 320x, the free layer 130x, the second insulating layer 340x, and a capping layer 150x may form a stack structure to be described with reference to FIG. 7E before an etching process is performed.

Referring to FIG. 7A, the lower electrode layer 101x and the pinned layer 110x may sequentially be formed on a lower structure 5.

A method of forming the lower electrode layer 101x and the pinned layer 110x may be similar to that described with reference to FIGS. 3A through 3C.

Referring to FIG. 7B, the first insulating layer 320x may be formed on the pinned layer 110x. The first insulating layer 320x may be formed of, for example, a metal oxide including one or more of Mg, Al, Ti, Ta, Hf, or Zr. Hereinafter, a case where the first insulating layer 320x is formed of MgO will be described for convenience.

The first insulating layer 320x may be formed through, for example, a DC sputtering process, an RF sputtering process, an ion sputtering process, a magnetron sputtering process, or an UHV sputtering process. In some embodiments, the first insulating layer 320x may be formed through a sputtering process in which a metal oxide such as MgO is used as a sputtering target. In other embodiments, a sputtering target of the first insulating layer 320x may be a metal such as Mg and may be formed through a sputtering process, which may be performed in an atmosphere in which oxygen and an inert gas are mixed. The first insulating layer 320x may be performed through a sputtering process in which a metal such as Mg is used as a sputtering target and an additional process in which a metal layer formed of the metal such as Mg is oxidized.

The first insulating layer 320x may be formed using a sputtering gas, which may be a gas mixture in which a first gas and a second gas are mixed.

The first gas may include an inert gas having a greater atomic weight than Ar. For example, the first gas may include one or more of Kr, Xe, or Rn. The second gas may be Ar gas.

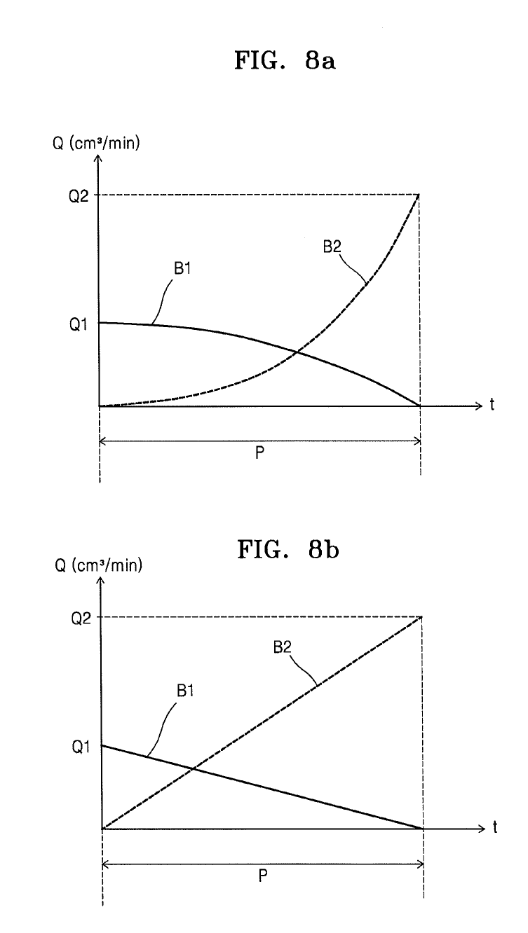

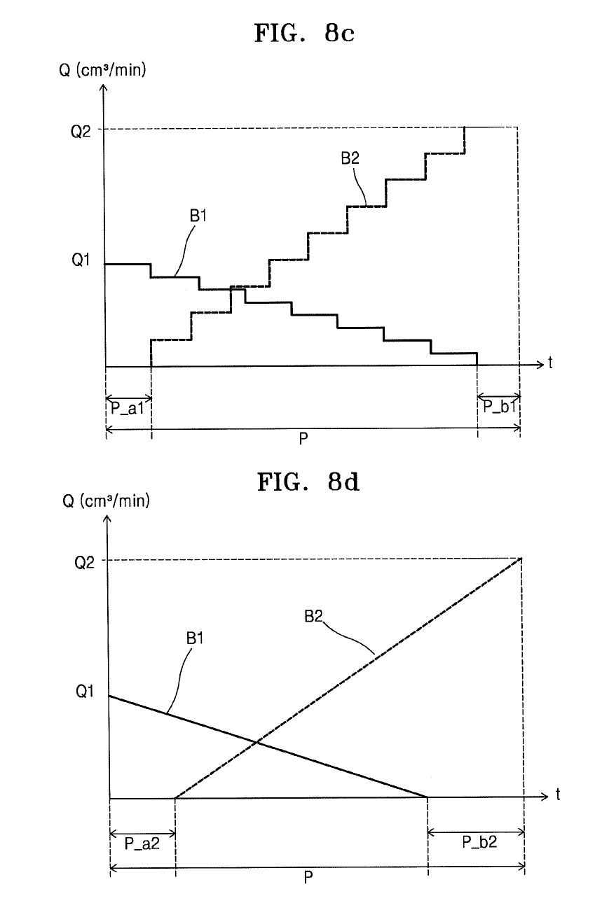

In some embodiments, a content ratio of the first gas in the gas mixture is gradually decreased as time passes, and a content ratio of the second gas in the gas mixture may be gradually increased (refer to B1 and B2 of FIGS. 8A through 8D).

In other embodiments, the content ratio of the first gas in the gas mixture is linearly decreased, and the content ratio of the second gas in the gas mixture may be linearly increased (refer to B1 and B2 of FIG. 8B).

When the first insulating layer 320x is formed using the gas mixture, the content ratio of the first gas is gradually decreased as time passes, and when the content ratio of the second gas in the gas mixture is gradually increased, formation of the damage layer DL (refer to FIGS. 2A and 2B) formed of, for example, FeO, on an interface between the first insulating layer 320x and the pinned layer 110x may be reduced or controlled.

Referring to FIG. 7C, an HT process may be performed on a stack structure including the first insulating layer 320x. The first insulating layer 320x may indicate an amorphous MgO layer, which may exist before the HT process is performed, and the first insulating layer 320y may indicate a crystalline MgO layer, which may exist after the HT process is performed. A detailed description of the HT process has already been provided with reference to FIG. 3E, and will be omitted here.

Referring to FIG. 7D, the free layer 130x, the second insulating layer 340x, and the capping layer 150x may sequentially be formed on the first insulating layer 320x. In the stack structure 3x, exemplary locations of the pinned layer 110x and the free layer 130x are illustrated in FIG. 7D; the locations of pinned layer 110x and the free layer 130x may be exchanged with each other. In an exemplary embodiment, in the stack structure 3x, layers from the lower electrode layer 101x to the capping layer 150x may be sequentially stacked. According to desired properties of a magnetic device, various types of layers may be added or may replace other layers in the stack structure 3x.

Referring to FIG. 7E, conductive mask patterns 160 may be formed on the stack structure 3x, and then the magnetic device 30 may be completed by performing a process similar to the process that is described with reference to FIGS. 3H through 3K.

FIGS. 8A through 8D illustrate graphs of a temporal change of flow of a sputtering gas in a chamber during a manufacturing process of a magnetic device, according to embodiments. In FIGS. 8A through 8D, an X axis indicates time (t), and a Y axis indicates a sputtering gas. Referring to FIGS. 8A through 8D, a gas mixture in which a first gas B1 and a second gas B2 are mixed is used in a P process.

The first gas B1 may include an inert gas having a greater atomic weight than Ar. For example, the first gas B1 may include one or more of Kr, Xe, or Rn. The second gas B2 may be, for example, Ar gas.

While the P process is performed, flow or a content ratio of the first gas B1 in the gas mixture is gradually decreased as time passes, and flow or a content ratio of the second gas B2 is gradually increased.

In some embodiments, flow of each of the first gas B1 and the second gas B2 may be non-linearly decreased or increased (refer to FIGS. 8A, 8C, and 8D). For example, flow of each of the first gas B1 and the second gas B2 may be exponentially decreased or increased or may be decreased or increased in a stepwise form.

In other embodiments, flow of each of the first gas B1 and the second gas B2 may be linearly decreased or increased (refer to FIG. 8B).

In each embodiment, initial flow Q1 of the first gas B1 ranges from about 1 to about 50 cm³/min, and final flow Q2 of the second gas B2 may range from about 50 to about 150 cm³/min.

In some embodiments, as illustrated in FIGS. 8C and 8D, only the first gas B1 may be used as a sputtering gas during early sections P_a1 and P_a2 of the P process. In other embodiments, only the second gas B2 may be used as a sputtering gas during back-end sections P_b1 and P_b2 of the P process.

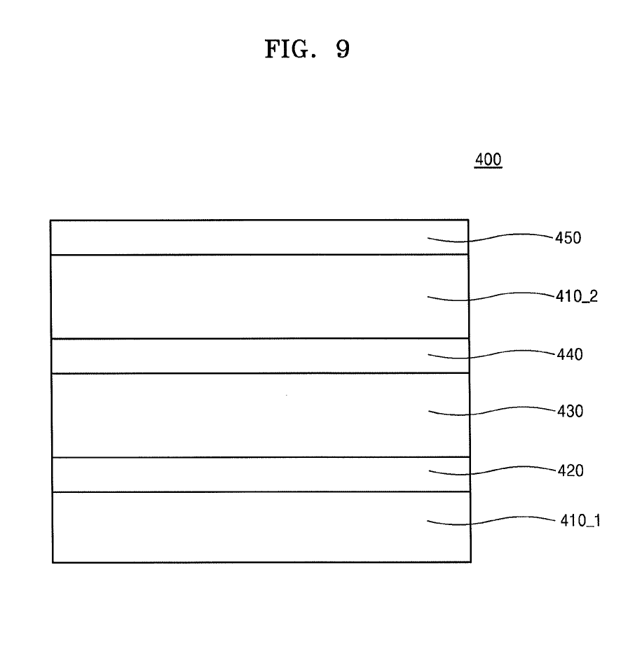

FIG. 9 illustrates a cross-sectional view of an MTJ structure 400 according to another embodiment.

The MTJ structure 400 of FIG. 9 has a dual MTJ structure.

The MTJ structure 400 may include a lower pinned layer 410_1, a first insulating layer 420, a free layer 430, a second insulating layer 440, an upper pinned layer 410_2, and a third insulating layer 450.

The first insulating layer 420 may be formed on the lower pinned layer 410_1, and the free layer 430 having a variable magnetization orientation may be formed on the first insulating layer 420. The second insulating layer 440 may be formed on the free layer 430, and the upper pinned layer 410_2 may be formed on the second insulating layer 440. The third insulating layer 450 may be formed on the upper pinned layer 410_2.

The lower pinned layer 410_1 may provide a stable switching property by offsetting a stray magnetic field in the upper pinned layer 410_2. Each of the lower pinned layer 410_1 and the upper pinned layer 410_2 may have a structure similar to the structure of the pinned layer 110 described with reference to FIG. 1B.

The free layer 430 may be a magnetic layer having a variable magnetization orientation. The free layer 430 may be formed of a different material or the same material as that used to form the lower pinned layer 410_1 or the upper pinned layer 410_2.

As shown in FIG. 9, the first insulating layer 420 may be interposed between the magnetic layers 410_1 and 430, and the second insulating layer 440 may be interposed between the magnetic layers 430 and 410_2. The first insulating layer 420 and the second insulating layer 440 increase a TMR of the MTJ structure 400. The first and second insulating layers 420 and 440 may have structures similar to those of the first insulating layers 120 and 320 described with reference to FIGS. 1B and 6. The first insulating layer 420 and the second insulating layer 440 may be formed through a process similar to the processes for forming the first insulating layers 120x and 320x described with reference to FIGS. 1A through 8D.

The third insulating layer 450 may be formed on an upper surface of the upper pinned layer 410_2 and may reinforce IPMA of the upper pinned layer 410_2. The third insulating layer 450 may have a structure similar to the structures of the second insulating layers 140 and 340 described with reference to FIGS. 1B and 6. The third insulating layer 450 may be formed through a process similar to the processes for forming the second insulating layers 140x and 340x described with reference to FIGS. 1A through 8D.

When a current is provided through the MTJ structure 400, switching of the free layer 430 in magnetic states may be performed. Since the MTJ structure 400 has the dual MTJ structure, a highly integrated magnetic memory device may provide improved performance.

In the MTJ structure 400 of FIG. 9, a resistance value of the MTJ structure 400 may differ according to orientations of electrons flowing through the dual MTJ structure, and data may be stored in a memory cell including the MTJ structure 400 by using a difference in resistance values.

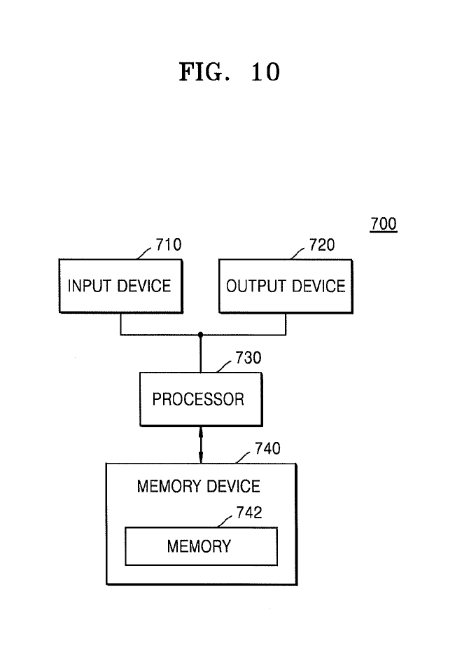

FIG. 10 illustrates a block diagram of an electronic system 700 including the magnetic devices according to embodiments. Referring to FIG. 10, the electronic system 700 may include an input device 710, an output device 720, a processor 730, and a memory device 740. In some embodiments, the memory device 740 may include a cell array including a non-volatile memory cell and peripheral circuits for operations such as a reading operation, and a writing operation. In other embodiments, the memory device 740 may include a non-volatile memory device and a memory controller.

A memory 742 included in the memory device 740 may include the magnetic devices described with reference to FIGS. 1A through 9.

The processor 730 may be respectively connected to the input device 710, the output device 720, and the memory device 740 through an interface and may control overall operations.

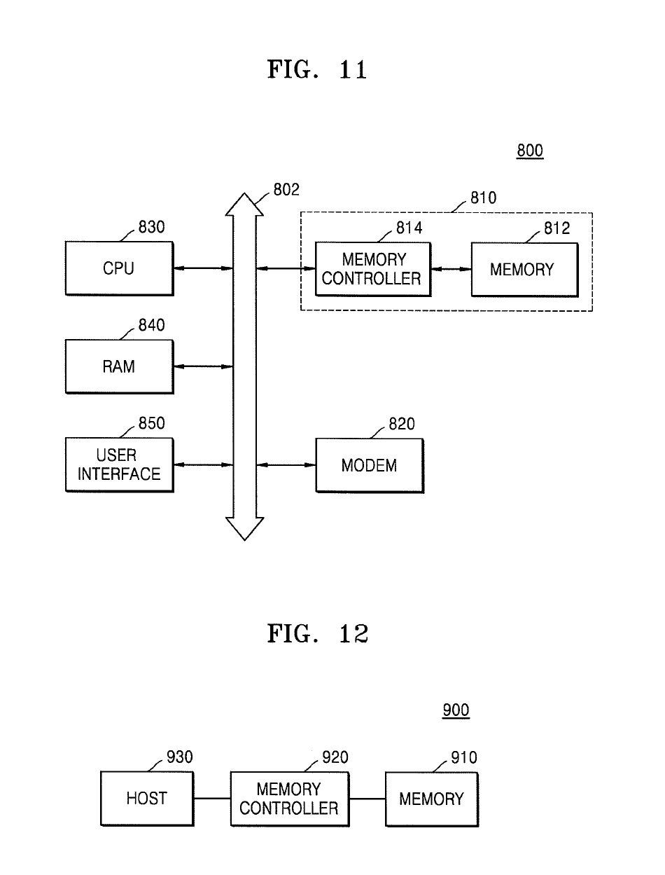

FIG. 11 illustrates a block diagram of an information processing system 800 including the magnetic devices according to embodiments. Referring to FIG. 11, the information processing system 800 may include a non-volatile memory system 810, a modem 820, a central processing unit (CPU) 830, a random access memory (RAM) 840, and a user interface 850, which may be electrically connected to a bus 802.

The non-volatile memory system 810 may include a memory 812 and a memory controller 814. Data processed by the CPU 830 or input by an external device is stored in the non-volatile memory system 810.

The non-volatile memory system 810 may include a non-volatile memory such as a magnetic RAM (MRAM), a phase-change RAM (PRAM), and a ferroelectrics RAM (FRAM). One or more of the memory 812 or the RAM 840 may include the magnetic devices described with reference to FIGS. 1A through 9.

The information processing system 800 may be used for a portable computer, a web tablet, a wireless phone, a mobile phone, a digital music player, a memory card, a MP3 player, a navigation device, a portable multimedia player (PMP), a solid state disk (SSD), or household appliances.

FIG. 12 illustrates a memory card 900 including the magnetic devices according to some embodiments.

The memory card 900 may include a memory 910 and a memory controller 920.

The memory 910 may store data. In some embodiments, the memory 910 may keep data even when power is not being supplied, and the memory 910 may be non-volatile. The memory 910 may include the magnetic devices described with reference to FIGS. 1A through 9.

The memory controller 920 may read data stored in the memory 910 or may store data of the memory 910 in response to reading/writing operations of a host 930.

By way of summation and review, electronic devices may use a magnetic resistance property of a MTJ. For example, it may be necessary to form a fine-sized MTJ structure to implement a STT-MRAM, and to secure a sufficient level of IPMA in a magnetic layer having the fine-sized MTJ structure. A method of manufacturing a magnetic device may be required, which may prevent deterioration of a crystal structure of an insulating layer and of the IPMA of the magnetic layer having the MTJ structure, which may occur while the insulating layer is formed on a surface of the magnetic layer.

Provided is a method of manufacturing a magnetic device which may prevent deterioration of a magnetic device, which may occur while an insulating layer included in the magnetic device is formed, and may maintain the reliability of the magnetic device. For example, the method may prevent deterioration of a crystal structure of an insulating layer and deterioration of IPMA of the magnetic layer, which may occur while the insulating layer is formed on a surface of the magnetic layer having the fine-sized MTJ structure.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a magnetic device, the method comprising:
forming a magnetic layer;
forming a lower insulating layer on the magnetic layer using a first gas, which is an inert gas having a greater atomic weight than argon (Ar); and
forming an upper insulating layer on the lower insulating layer using Ar gas.

2. The method as claimed in claim 1, wherein the magnetic layer is a pinned layer or a free layer.

3. The method as claimed in claim 1, wherein forming the lower insulating layer is performed under a pressure ranging from about 0.001 to about 0.1 mTorr.

4. The method as claimed in claim 1, wherein forming the lower insulating layer includes a sputtering process in which a metal oxide is used as a target.

5. The method as claimed in claim 1, wherein the first gas is krypton (Kr) gas.

6. A method of manufacturing a magnetic device, the method comprising:
forming a first lower insulating layer on a first magnetic layer;
forming a first upper insulating layer on the first lower insulating layer;
forming a second magnetic layer on the first upper insulating layer; and
forming a second insulating layer on the second magnetic layer,
the first lower insulating layer being formed using a first gas, which is an inert gas having a greater atomic weight than argon (Ar), and
the first upper insulating layer being formed using Ar gas.

7. The method as claimed in claim 6, wherein:
either the first magnetic layer or the second magnetic layer is a pinned layer, and
the other of the first magnetic layer and the second magnetic layer is a free layer.

8. The method as claimed in claim 6, wherein the first lower insulating layer directly contacts the first upper insulating layer.

9. The method as claimed in claim 6, wherein forming the second insulating layer includes a sputtering process in which the first gas is used as a sputtering gas.

10. The method as claimed in claim 6, further comprising, after forming the first lower insulating layer, a first heat treatment process in which the first lower insulating layer is heat-treated and a damage layer formed on an interface between the first magnetic layer and the first lower insulating layer is removed.

11. The method as claimed in claim 10, further comprising, after forming the first lower insulating layer, performing a second heat treatment process in which the first lower insulating layer is heat-treated at a temperature higher than a temperature of the first heat treatment process and the first lower insulating layer is crystallized.

12. The method as claimed in claim 11, wherein the first and second heat processes are performed in an in-situ manner after forming the first lower insulating layer.

13. The method as claimed in claim 6, further comprising performing a third heat treatment process in which the second insulating layer is heat-treated after forming the second insulating layer.

14. The method as claimed in claim 6, wherein one or more of the first lower insulating layer, the first upper insulating layer, or the second insulating layer includes a metal oxide.

15. The method as claimed in claim 14, wherein the metal oxide includes one or more of aluminum (Al), magnesium (Mg), tantalum (Ta), hafnium (Hf), or zirconium (Zr).

16. A method of manufacturing a magnetic device, the method comprising:
forming a magnetic layer;
forming a lower insulating layer on the magnetic layer, including a sputtering process using a sputtering gas, the sputtering gas including Ar gas and an inert gas having a greater atomic weight than Ar; and
heat treating the lower insulating layer.

17. The method as claimed in claim 16, wherein, during formation of the lower insulating layer:
a flow of the inert gas having a greater atomic weight than Ar is decreased,
a flow of Ar gas is increased, and
at a point in time, the flow of the inert gas having a greater atomic weight than Ar is equal to the flow of Ar gas.

18. The method as claimed in claim 17, wherein an initial flow of the inert gas having a greater atomic weight than Ar is less than or equal to a final flow of Ar gas.

19. The method as claimed in claim 16, wherein only the inert gas having a greater atomic weight than Ar is used during an early stage of the sputtering process.

20. The method as claimed in claim 19, wherein only Ar gas is used during a late stage of the sputtering process.
